(19) United States
(12) Patent Application Publication
(10) Pub. No.: US 2014/0183752 A1
(43) Pub. Date: Jul. 3, 2014

(54) SEMICONDUCTOR ASSEMBLY WITH BUILT-IN STOPPER, SEMICONDUCTOR DEVICE AND BUILD-UP CIRCUITRY AND METHOD OF MAKING THE SAME

(71) Applicant: BRIDGE SEMICONDUCTOR CORPORATION, Taipei City (TW)

(72) Inventors: Charles W.C. LIN, Singapore (SG); Chia-Chung WANG, Hsinchu (TW)

(73) Assignee: Bridge Semiconductor Corporation, Taipei City (TW)

(21) Appl. No.: 13/733,226

(22) Filed: Jan. 3, 2013

(51) Int. Cl. H01L 21/58; H01L 23/485

(52) U.S. Cl. CPC H01L 21/58
USPC 257/774; 438/118; 438/126

(57) ABSTRACT

The present invention relates to a semiconductor assembly with a built-in stopper and a method of making the same. In accordance with one preferred embodiment of the present invention, the method includes: forming a stopper on a dielectric layer; mounting a semiconductor device on the dielectric layer using the stopper as a placement guide for the semiconductor device; attaching a stiffener to the dielectric layer; and forming a build-up circuitry that covers the semiconductor device, the stopper and the stiffener and provides signal routing for the semiconductor device. Accordingly, the stopper can accurately confine the placement location of the semiconductor device and avoid the electrical connection failure between the semiconductor device and the build-up circuitry.

### CROSS-REFERENCE TO RELATED APPLICATIONS

This application claims the benefit of filing date of U.S. Provisional Application Ser. No. 61/682,801, entitled “Structure and Manufacture of Semiconductor Assembly and 3D Stacking thereof” filed Aug. 14, 2012 under 35 USC §119(e)(1).

### BACKGROUND OF THE INVENTION

1. Field of the Invention

The present invention relates to a semiconductor assembly and a method of making the same, and more particularly to a semiconductor assembly with a built-in stopper, a semiconductor device and build-up circuitry and a method of making the same.

2. Description of Related Art

As market trend demands for thinner, smarter and cheaper portable electronics, semiconductor devices for use in these equipments are required to further shrink their size and improve electrical performances at lower cost. Among all the efforts, embedding or built-in semiconductor chip in printed wiring board to form a module assembly is considered the most effective approach since it can drastically reduce the overall weight, thickness and improve electrical performance through a shorten interconnect distance.

However, the attempt of embedding chip in a wiring board can encounter many problems. For example, the chip to be embedded is known to vertically and laterally shift during die attach and encapsulation/lamination processes due to thermal characteristics of plastic materials. The CTE mismatch between metal, dielectric and silicon at various stages of thermal treatment can result in misalignment of the build-up interconnect structure to be deposited thereon. U.S. Pat. No. 7,935,893 to Tanaka et. al., U.S. Pat. No. 7,944,039 to Aral and U.S. Pat. No. 7,405,103 to Chang disclose various alignment methods to address manufacturing yield concern. None of these approaches offers a proper solution or effective method for controlling die movement because the underneath adhesive will reflow during curing and therefore dislocates the attached die from the pre-determined location even a highly precise alignment mark and equipment are applied. U.S. Patent Application 2010/0184256 to Chino discloses a resin sealing method to fix the semiconductor device adhered to the adhesive layer formed on the support body. This approach may be effective in controlling die from further movement during sealing process, it does not provide any control or adjustment for die attach process and the mis-registration is unavoidable due to die attach adhesive reflows.

### SUMMARY OF THE INVENTION

The present invention has been developed in view of such a situation, and an object thereof is to provide a semiconductor assembly in which a semiconductor device is precisely affixed at a predetermined location and electrical connection between the semiconductor device and the build-up circuitry can be securely retained by conductive via.

In one preferred embodiment, the present invention provides a method of making a semiconductor assembly that includes a semiconductor device, a stopper, a stiffener and build-up circuitry. The method of making a semiconductor assembly with a stiffener can include: forming a stopper on a dielectric layer; mounting a semiconductor device on the dielectric layer using the stopper as a placement guide for the semiconductor device that includes an active surface with a contact pad thereon and an inactive surface, wherein the active surface faces a first vertical direction, the inactive surface faces a second vertical direction opposite the first vertical direction, and the stopper is located in close proximity to and laterally aligned with and laterally extends beyond peripheral edges of the semiconductor device in lateral directions orthogonal to the vertical directions; attaching a stiffener to the dielectric layer, including aligning the semiconductor device and the stopper within an aperture of the stiffener; and forming a build-up circuitry that covers the stopper, the semiconductor device and the stiffener in the first vertical direction and includes a first conductive via that directly contacts the contact pad of the semiconductor device to provide an electrical connection between the semiconductor device and the build-up circuitry.

The semiconductor device can be mounted on the dielectric layer with the active surface facing the dielectric layer and the stopper extends from the dielectric layer in the second vertical direction. Alternatively, the semiconductor device may be mounted on the dielectric layer with the inactive surface facing the dielectric layer and the stopper extends from the dielectric layer in the first vertical direction.

In another preferred embodiment, the present invention provides a method of making another semiconductor assembly that includes a semiconductor device, a stopper, an encapsulant and build-up circuitry. The method for making a semiconductor assembly with an encapsulant can include: forming a stopper on a dielectric layer; mounting a semiconductor device on the dielectric layer using the stopper as a placement guide for the semiconductor device that includes an active surface with a contact pad thereon and an inactive surface, wherein the active surface faces a first vertical direction and is attached to the dielectric layer, the inactive surface faces a second vertical direction opposite the first vertical direction, and the stopper is located in close proximity to and laterally aligned with and laterally extends beyond peripheral edges of the semiconductor device in lateral directions orthogonal to the vertical directions; depositing an encapsulant that covers the semiconductor device, the stopper and the dielectric layer from the second vertical direction and extends laterally from the semiconductor device and the stopper to peripheral edges of the assembly; and forming a build-up circuitry that covers the stopper, the semiconductor device and the stiffener in the first vertical direction and includes a first conductive via that extends through the dielectric layer and directly contacts the contact pad of the semiconductor device to provide an electrical connection between the semiconductor device and the build-up circuitry.

The build-up circuitry can include a first insulating layer, one or more first via openings and one or more first conductive traces. For instance, the first insulating layer covers the semiconductor device, the stopper and the stiffener or the encapsulant in the first vertical direction and can extend to peripheral edges of the assembly, and the first conductive traces extend from the first insulating layer in the first vertical direction. As a result, forming the build-up circuitry can include: providing a first insulating layer that covers the stopper, the semiconductor device, and the stiffener or the encapsulant in the first vertical direction; then forming one or more first via openings that extend through the first insulating layer and are aligned with one or more contact pads of the semiconductor device and optionally one or more additional first via openings that extend through the first insulating layer and are aligned with the stiffener; and then providing one or more first conductive traces that extend from the first insulating layer in the first vertical direction and extend laterally on the first insulating layer and extend through the first via openings and optionally the additional first via openings in the second vertical direction to form one or more first conductive vias in direct contact with the contact pads of the semiconductor device and optionally one or more additional first conductive vias in direct contact with the stiffener. Accordingly, the first conductive traces can directly contact the contact pads to provide signal routing for the semiconductor device, and thus the electrical connection between the semiconductor device and the build-up circuitry can be devoid of solder. The first conductive traces can also directly contact the stiffener for grounding or electrical connections to passive components such as thin film resistors or capacitors deposited thereon. In the case that the active surface of the semiconductor device faces the dielectric layer, the first insulating layer of the build-up circuitry includes the dielectric layer, and the first via opening extends through the dielectric layer.

The build-up circuitry can further include additional insulating layer, additional via openings, and additional conductive traces if needed for further signal routing. For instance, the build-up circuitry can further include a second insulating layer, one or more second via openings and one or more second conductive traces. The second insulating layer can extend from the first insulating layer and the first conductive trace in the first vertical direction and can extend to peripheral edges of the assembly, and the second conductive traces extend from the second insulating layer in the first vertical direction. As a result, forming the build-up circuitry can further include: providing a second insulating layer on the first insulating layer and the first conductive trace that extends from the first insulating layer and the first conductive trace in the first vertical direction; then forming one or more second via openings that extend through the second insulating layer and are aligned with the first conductive trace; and then forming one or more second conductive traces that extend from the second insulating layer in the first vertical direction and extend laterally on the second insulating layer and extend through the second via openings in the second vertical direction to form one or more second conductive vias in direct contact with the first conductive traces, thereby electrically connecting the first conductive trace to the second conductive traces. The first via openings and the second via openings can have the same size, and the first insulating layer, the first conductive traces, the second insulating layer and the second conductive traces can have flat elongated surfaces that face in the first vertical direction.

The build-up circuitry can include one or more interconnect pads to provide electrical contacts for the next level assembly or another electronic device such as a semiconductor chip, a plastic package or another semiconductor assembly. The interconnect pads can extend to or beyond the first conductive traces in the first vertical direction and include an exposed contact surface that faces in the first vertical direction. For instance, the interconnect pad can be adjacent to and integral with the second conductive trace. The first conductive trace and the second conductive trace can provide an electrical interconnection between the interconnect pad and the contact pad of the semiconductor device. As a result, the next level assembly or another electronic device can be electrically connected to the embedded semiconductor device using a wide variety of connection media including gold or solder bumps on the electrical contacts (i.e. the interconnect pads of the build-up circuitry).

Forming the stopper on the dielectric layer can include: providing a laminate substrate that includes a metal layer and the dielectric layer; and then removing a selected portion of the metal layer to form the stopper. Alternatively, forming the stopper on the dielectric layer can include: providing a laminate substrate that includes a metal layer and the dielectric layer; then removing a selected portion of the metal layer to form a recessed portion; then depositing a plastic material into the recessed portion as the stopper; and then removing a remaining portion of the metal layer. Accordingly, the stopper can be made of a metal, a photosensitive plastic material or non-photosensitive material. For instance, the stopper can consist essentially of copper, aluminum, nickel, iron, tin or their alloys. The stopper can also consist of epoxy or polyimide.

The method of making a semiconductor assembly with a stiffener according to the present invention can further include: forming a placement guide on the dielectric layer. Accordingly, attaching the stiffener to the dielectric layer can include: aligning the semiconductor device and the stopper within the aperture of the stiffener with the placement guide being in close proximity to and laterally aligned with and laterally extending beyond the outer peripheral edges of the stiffener in lateral directions.

Forming the stopper and the placement guide on the dielectric layer can include: providing a laminate substrate that includes a metal layer and the dielectric layer; and then removing a selected portion of the metal layer to form the stopper and the placement guide. Alternatively, forming the stopper and the placement guide on the dielectric layer can include: providing a laminate substrate that includes a metal layer and the dielectric layer; then removing a selected portion of the metal layer to form a recessed portion; then depositing a plastic material into the recessed portion as the stopper and the placement guide; and then removing a remaining portion of the metal layer. Accordingly, like the stopper, the placement guide for the stiffener can be made of a metal, a photosensitive plastic material or non-photosensitive material, such as copper, aluminum, nickel, iron, tin, alloys, epoxy or polyimide.

The laminate substrate can optionally further include a support plate, and the dielectric layer can be sandwiched between the metal layer and the support plate. Accordingly, in the case that the active surface of the semiconductor device faces the dielectric layer, the method of making a semiconductor assembly according to the present invention can further include: removing the support plate or thinning the support plate after mounting the semiconductor device and attaching the stiffener or depositing the encapsulant. In the aspect of removing the support plate, the dielectric layer can serve as the first insulating layer of the build-up circuitry and is provided with the first via openings that extend through the dielectric layer, followed by forming the first conductive traces that extend from the dielectric layer in the first vertical direction and extend through the first via openings to the contact pads of the semiconductor device in the second vertical direction. Alternatively, a metal layer may be attached to the dielectric layer using an interlayer dielectric, and the combination of the dielectric layer and the interlayer dielectric serves as the first insulating layer of the build-up circuitry and is provided with the first via openings that extend through the dielectric layer and the interlayer dielectric, followed by forming the first conductive traces that include the metal layer and extend from the interlayer dielectric in the first vertical direction and extend through the first via openings to the contact pads of the semiconductor device in the second vertical direction. In the aspect of thinning the support plate, the dielectric layer can serve as the first insulating layer of the build-up circuitry, and the first conductive traces include the remaining portion of the support plate after the thinning process and extend from the dielectric layer in the first vertical direction and extends through the first via openings to the contact pads of the semiconductor device in the second vertical direction.

The semiconductor device can be attached to the dielectric layer using an adhesive that contacts and is sandwiched between the semiconductor device and the dielectric layer. Likewise, the stiffener can be attached to the dielectric layer using an adhesive that contacts and is sandwiched between the stiffener and the dielectric layer. In the case that the active surface of the semiconductor device faces the dielectric layer, the adhesive can contact and be coplanar with the stopper and the placement guide in the first vertical direction and lower than the stopper and the placement guide in the second vertical direction. Accordingly, the semiconductor device and the stiffener can be affixed and mechanically connected to the build-up circuitry at predetermined location defined by the stopper and the placement guide that extend from the first insulating layer of the build-up circuitry in the second vertical direction. As the adhesive is lower than the stopper and the placement guide in the second vertical direction, the stopper and the placement guide can stop the undesirable movement of the semiconductor device and the stiffener during curing the adhesive that contacts and is sandwiched between the active surface of the semiconductor device and the build-up circuitry and between the stiffener and the build-up circuitry. Likewise, in the case that the inactive surface of the semiconductor device faces the dielectric layer, the adhesive can contact and be coplanar with the stopper and the placement guide in the second vertical direction and lower than the stopper and the placement guide in the first vertical direction, such that the stopper and the placement guide can prevent the semiconductor device and the stiffener from undesirable movement before the adhesive is fully cured.

The insulating layers can be deposited and extend to peripheral edges of the assembly by numerous techniques including film lamination, roll coating, spin coating and spray-on deposition. The via openings can be formed through the insulating layers by numerous techniques including laser drilling, plasma etching and photolithography. The conductive traces can be formed by depositing a plated layer that covers the insulating layer in the first vertical direction and extends through the via opening to the contact pad and optionally to the stiffener, and then removing selected portions of the plated layer using an etch mask that defines the conductive trace. The plated layers can be deposited by numerous techniques including electroplating, electroless plating, evaporating, sputtering, and their combinations as a single layer or multiple layers. The plated layers can be patterned by numerous techniques including wet etching, electro-chemical etching, laser-assist etching, and their combinations to define the conductive traces.

By the above-mentioned method of making a semiconductor assembly with a stiffener, the present invention can provide a semiconductor assembly that includes: a semiconductor device that includes an active surface with a contact pad thereon and an inactive surface, wherein the active surface faces a first vertical direction and the inactive surface faces a second vertical direction opposite the first vertical direction; a stopper that serves as a placement guide for the semiconductor device and is in close proximity to and laterally aligned with and laterally extends beyond peripheral edges of the semiconductor device in lateral directions orthogonal to the vertical directions; a stiffener that includes an aperture with the semiconductor device and the stopper extending thereinto; and a build-up circuitry that covers the stopper, the semiconductor device and the stiffener in the first vertical direction and includes a first insulating layer, a first via opening and a first conductive trace, wherein the first via opening in the first insulating layer is aligned with the contact pad of the semiconductor device, and the first conductive trace extends from the first insulating layer in the first vertical direction and extends through the first via opening in the second vertical direction and directly contacts the contact pad. Optionally, the semiconductor assembly can further include: a placement guide that is in close proximity to and laterally aligned with and laterally extends beyond the outer peripheral edges of the stiffener in lateral directions orthogonal to the vertical directions.

By the above-mentioned method of making a semiconductor assembly with an encapsulant, the present invention can provide another semiconductor assembly that includes: a semiconductor device that includes an active surface with a contact pad thereon and an inactive surface, wherein the active surface faces a first vertical direction and the inactive surface faces a second vertical direction opposite the first vertical direction; a stopper that serves as a placement guide for the semiconductor device and is in close proximity to and laterally aligned with and laterally extends beyond peripheral edges of the semiconductor device in lateral directions orthogonal to the vertical directions; an encapsulant that covers the semiconductor device and the stopper from the second vertical direction and extends laterally from the semiconductor device and the stopper to peripheral edges of the assembly; and a build-up circuitry that covers the stopper, the semiconductor device and the encapsulant in the first vertical direction and includes a first insulating layer, a first via opening and a first conductive trace, wherein the first via opening in the first insulating layer is aligned with the contact pad of the semiconductor device, and the first conductive trace extends from the first insulating layer in the first vertical direction and extends through the first via opening in the second vertical direction and directly contacts the contact pad.

The stopper and the placement guide can have patterns against undesirable movement of the semiconductor device and the stiffener, respectively. For instance, the stopper and the placement guide can include a continuous or discontinuous strip or an array of posts. The stopper and the placement guide can be simultaneously formed and have the same or different patterns. Specifically, the stopper can be laterally aligned with four lateral surfaces of the semiconductor device to stop the lateral displacement of the semiconductor device. For instance, the stopper can be aligned along and conform to four sides, two diagonal corners or four corners of the semiconductor device and a gap in between the semiconductor device and the stopper preferably is in a range of about 0.001 to 1 mm. The semiconductor device can be spaced from the inner wall of the aperture by the stopper, and a bonding material can be added between the semiconductor device and the stiffener to enhance rigidity or the first insulating layer of the build-up circuitry may extend into and fill the gap between the semiconductor device and the stiffener. Moreover, the stopper can also be in close proximity to and laterally aligned with the inner wall of the aperture to stop the lateral displacement of the stiffener. Likewise, the placement guide can be laterally aligned with four outer lateral surfaces of the stiffener to stop the lateral displacement of the stiffener. For instance, the placement guide can be aligned along and conform to four outer sides, two outer diagonal corners or four outer corners of the stiffener and a gap in between the outer peripheral edges of the stiffener and the placement guide preferably is in a range of about 0.001 to 1 mm. Besides, the stopper and the placement guide preferably have a thickness in a range of 10-200 microns.

The stiffener can extend to peripheral edges of the assembly and provide mechanical support to suppress warp and bend of the semiconductor device. Moreover, the stiffener also can provide ground/power plane and heat sink for the build-up circuitry. The stiffener can be a single layer structure or a multi-layer structure (such as a circuit board or a multi-layer ceramic board or a laminate of a substrate and a conductive layer). For instance, the stiffener can be made of ceramics, metal or other various inorganic materials, such as aluminum oxide (Al₂O₃), aluminum nitride (AlN), silicon nitride (SiN), silicon (Si), glass, copper (Cu), aluminum (Al), stainless steel, etc. The stiffener can also be made of organic materials such as laminated epoxy, polyamide or copper-clad laminate.

The encapsulant can extend from the semiconductor device, the stopper and the build-up circuitry in the second vertical direction and laterally cover and surround and conformally coat the peripheral side surfaces of the semiconductor device and the stopper and extend laterally from the semiconductor device and the stopper to peripheral edges of the assembly to provide protection for the semiconductor device.

The present invention also provides a stacking module, comprising: plural semiconductor assemblies, each including (i) a semiconductor device that includes an active surface with a contact pad thereon and an inactive surface, wherein the active surface faces a first vertical direction and the inactive surface faces a second vertical direction opposite the first vertical direction, (ii) a stopper that serves as a placement guide for the semiconductor device and is in close proximity to and laterally aligned with and laterally extends beyond peripheral edges of the semiconductor device in lateral directions orthogonal to the vertical directions, (iii) a stiffener that includes an aperture with the semiconductor device and the stopper extending thereinto, (iv) a build-up circuitry that covers the stopper, the semiconductor device and the stiffener in the first vertical direction and includes a first insulating layer, a first via opening and a first conductive trace, wherein the first via opening in the first insulating layer is aligned with the contact pad of the semiconductor device, and the first conductive trace extends from the first insulating layer in the first vertical direction and extends through the first via opening in the second vertical direction and directly contacts the contact pad; one or more interlayer dielectrics that are sandwiched between each two neighboring ones of the semiconductor assemblies that are stacked in the vertical directions; and a plated through-hole that extends through the semiconductor assemblies and the interlayer dielectrics to provide an electrical connection between the semiconductor assemblies.

The semiconductor device can be a packaged or unpackaged semiconductor chip. For instance, the semiconductor device can be a land grid array (LGA) package or wafer level package (WLP) that includes a semiconductor chip. Alternatively, the semiconductor device can be a semiconductor chip.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips.

Unless specific descriptions or using the term “then” between steps or steps necessarily occurring in a certain order, the sequence of the above-mentioned steps is not limited to that set forth above and may be changed or reordered according to desired design.

The present invention has numerous advantages. The stiffener can provide a power/ground plane, a heat sink and a robust mechanical support for the semiconductor device and the build-up circuitry. The stopper can accurately confine the placement location of the semiconductor device and avoid the electrical connection failure between the semiconductor device and the build-up circuitry resulted from the lateral displacement of the semiconductor device, thereby improving the manufacturing yield greatly. The direct electrical connection without solder between the semiconductor device and the build-up circuitry is advantageous to high I/O and high performance. The semiconductor assembly is reliable, inexpensive and well-suited for high volume manufacture.

These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional views showing a method of forming a stopper on a dielectric layer in accordance with an embodiment of the present invention;

FIG. 2A is a top view corresponding to FIG. 2;

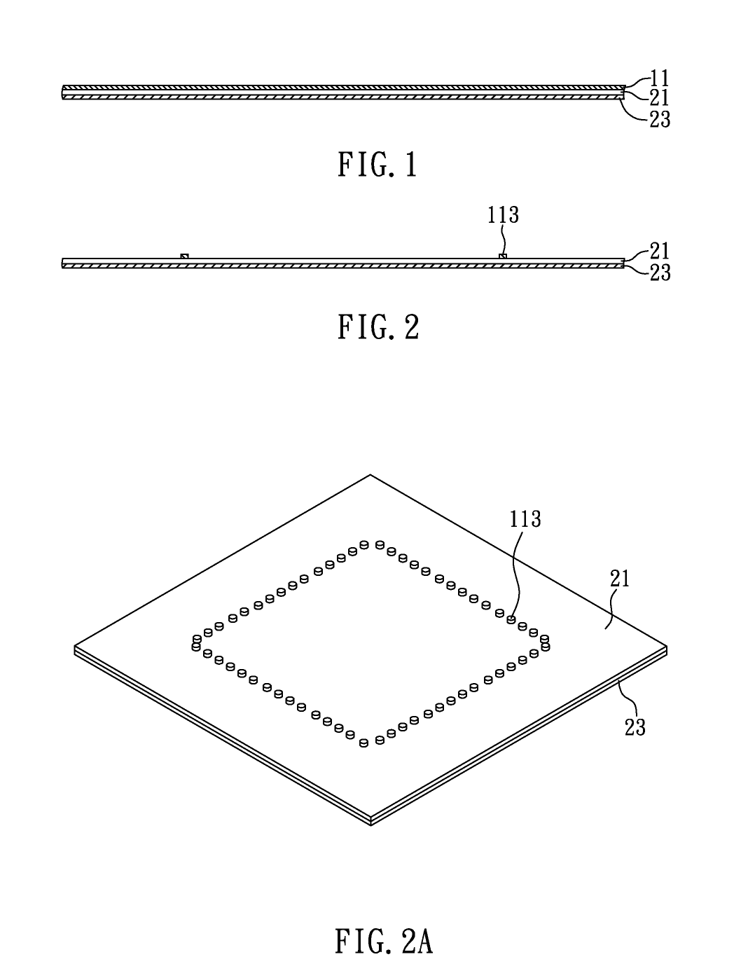

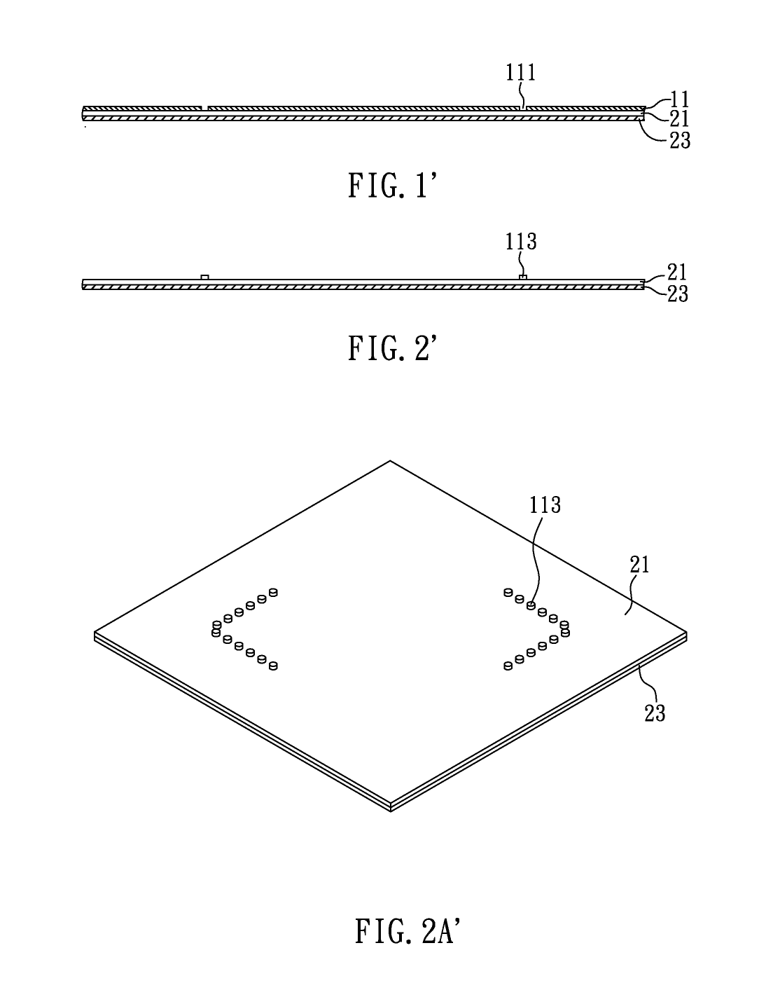

FIGS. 1′ and 2′ are cross-sectional views showing an alternative method of forming a stopper on a dielectric layer in accordance with an embodiment of the present invention;

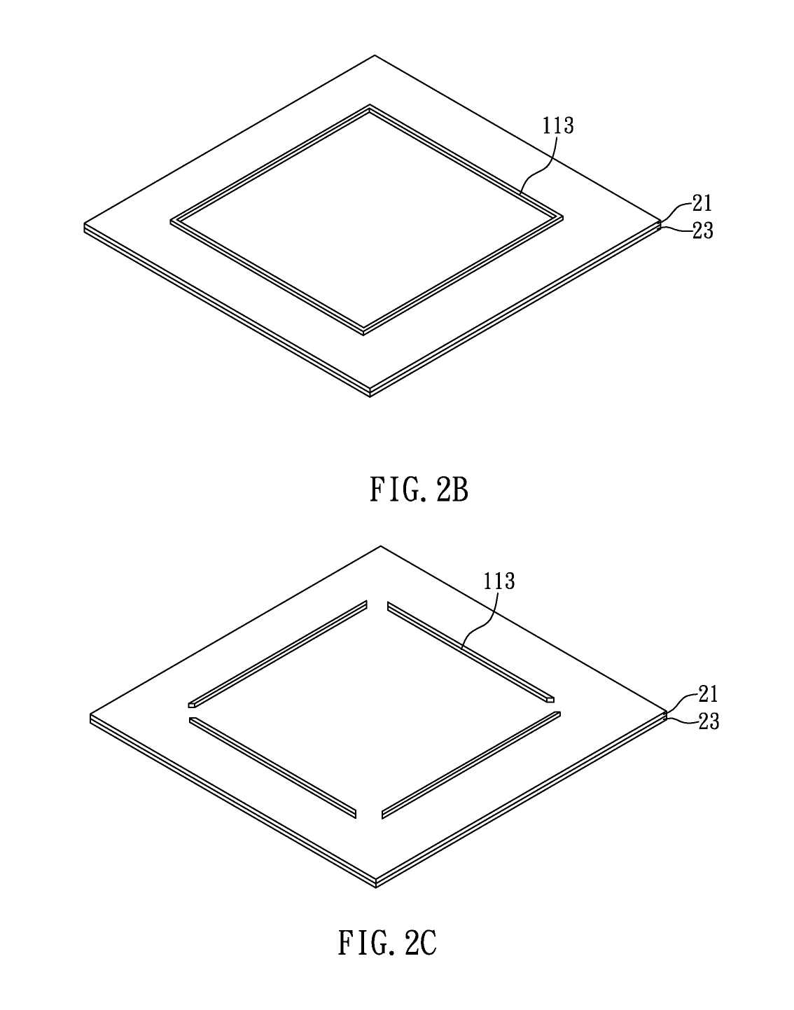

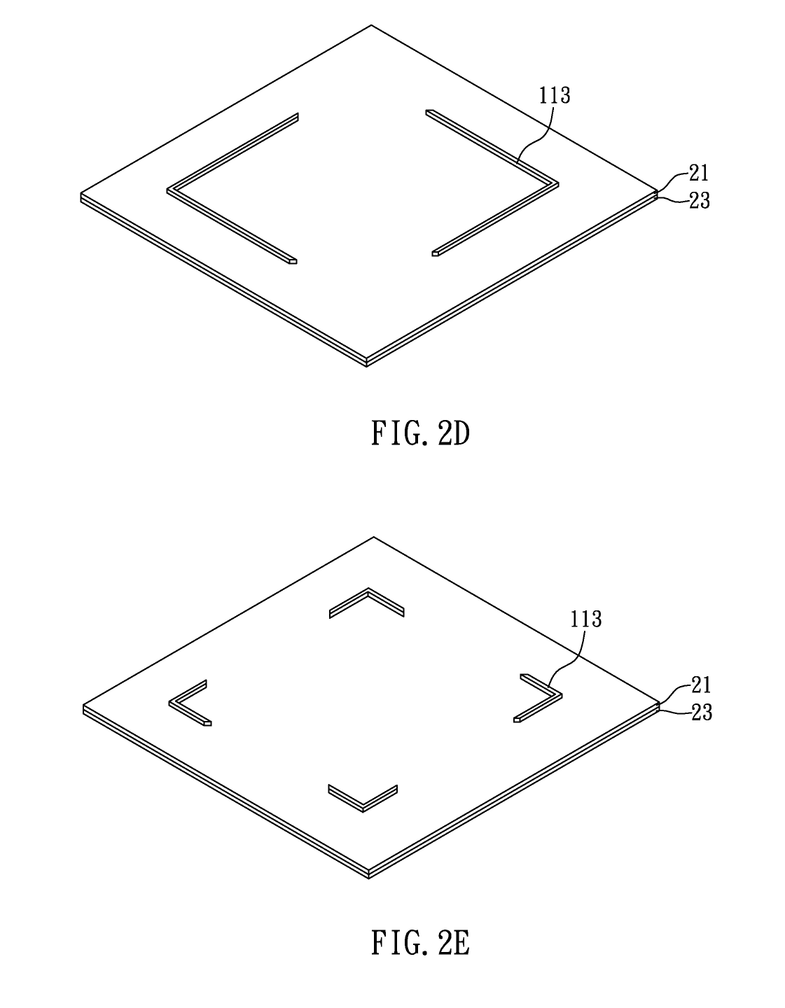

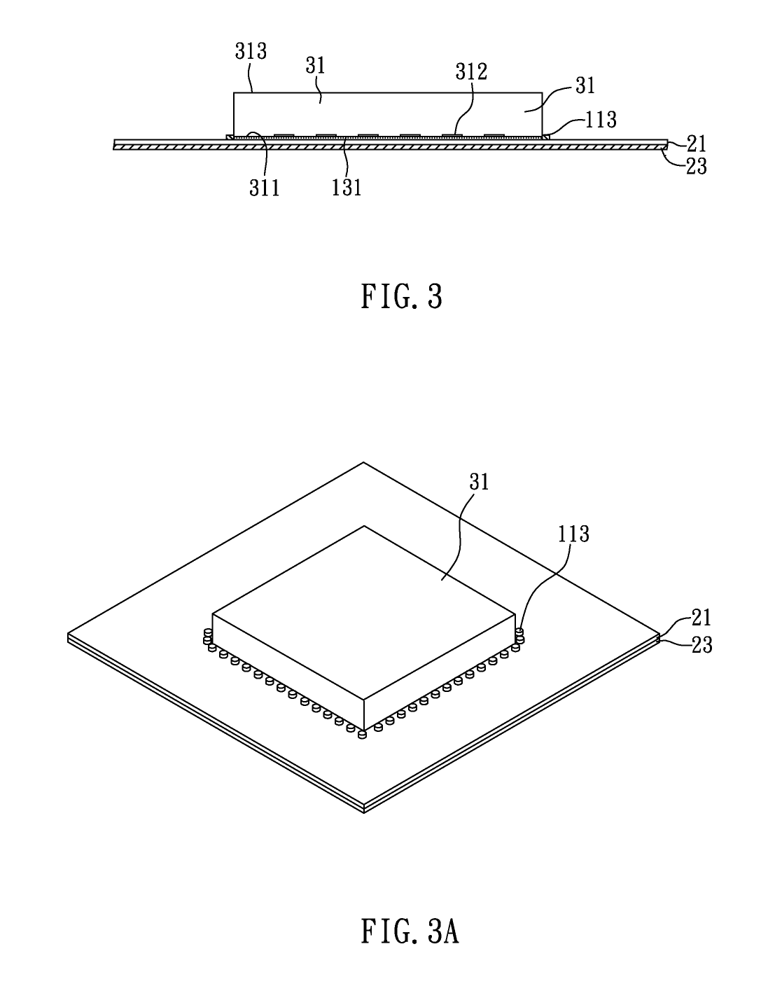

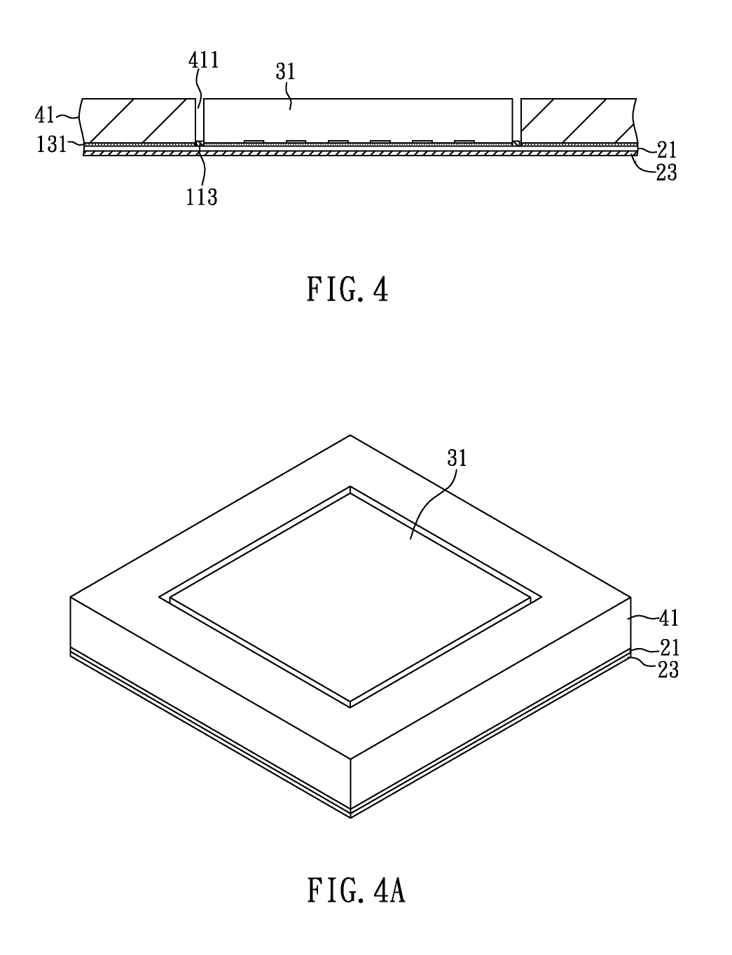

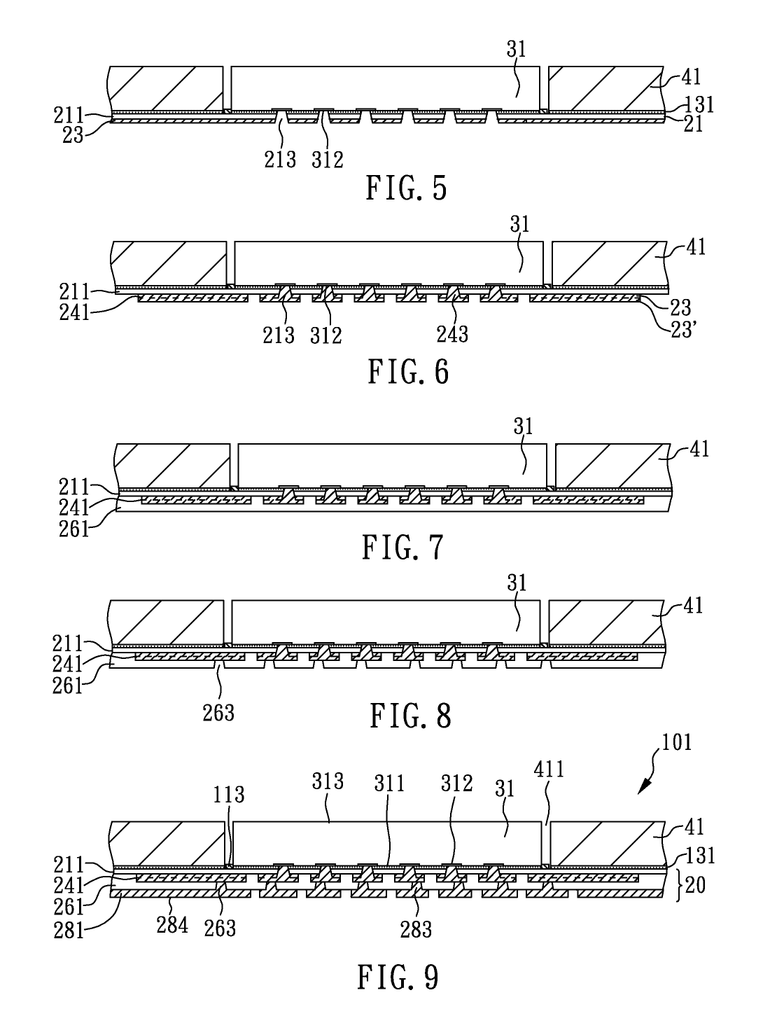

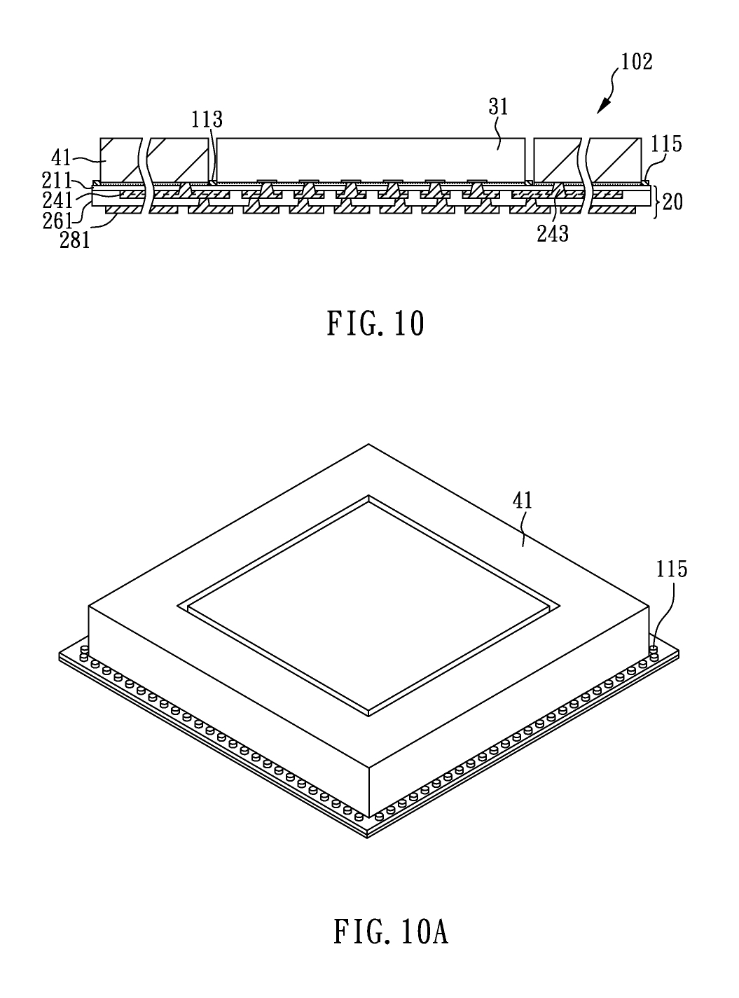

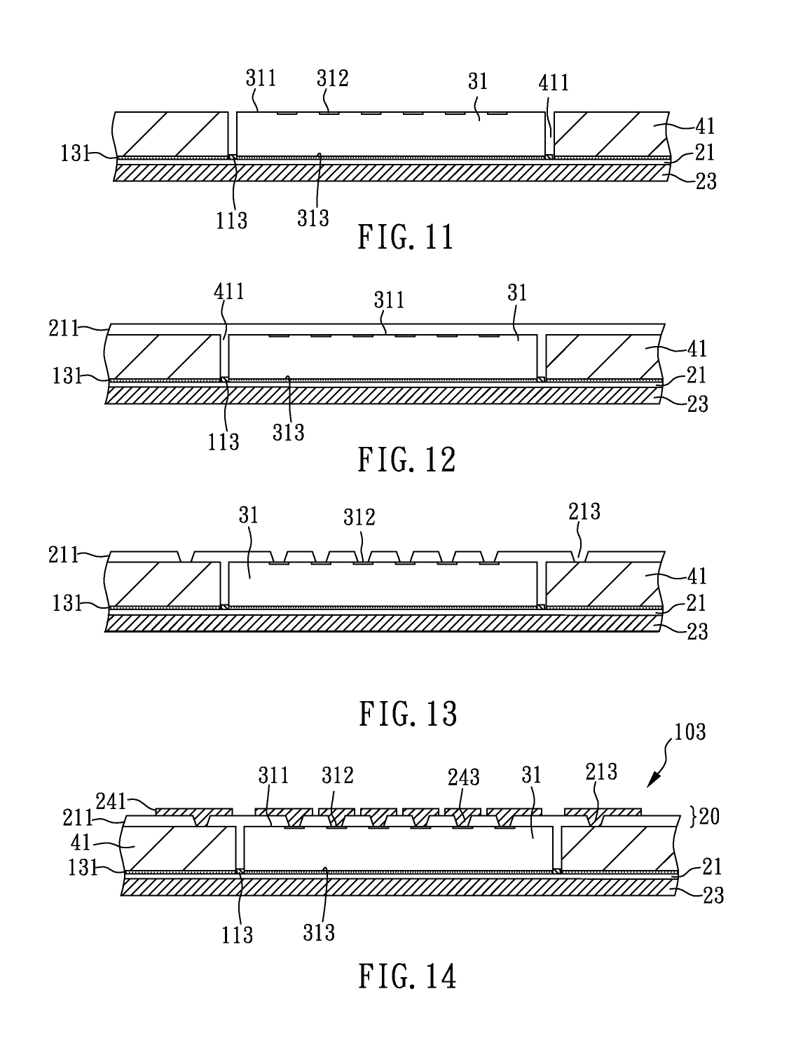

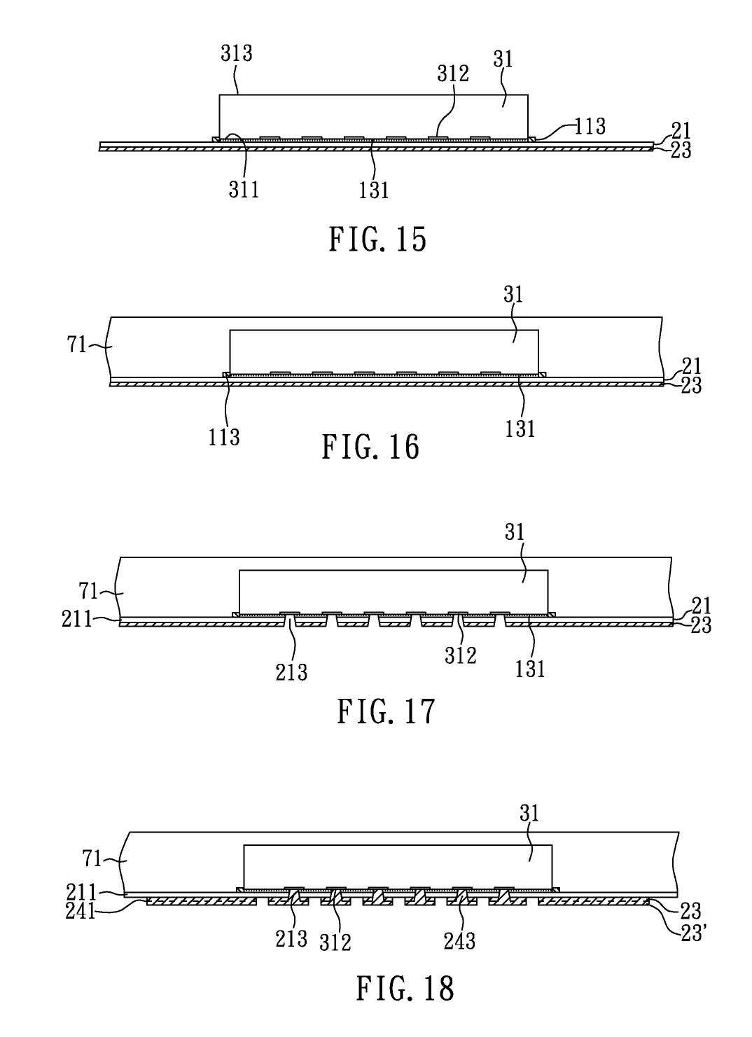

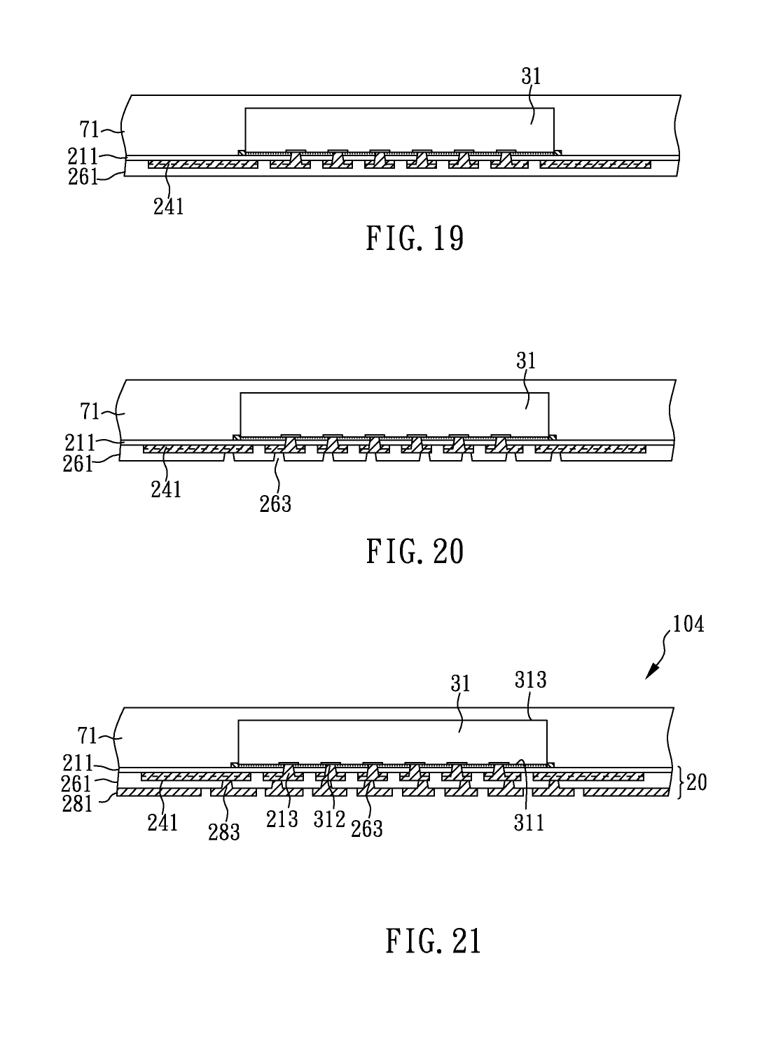

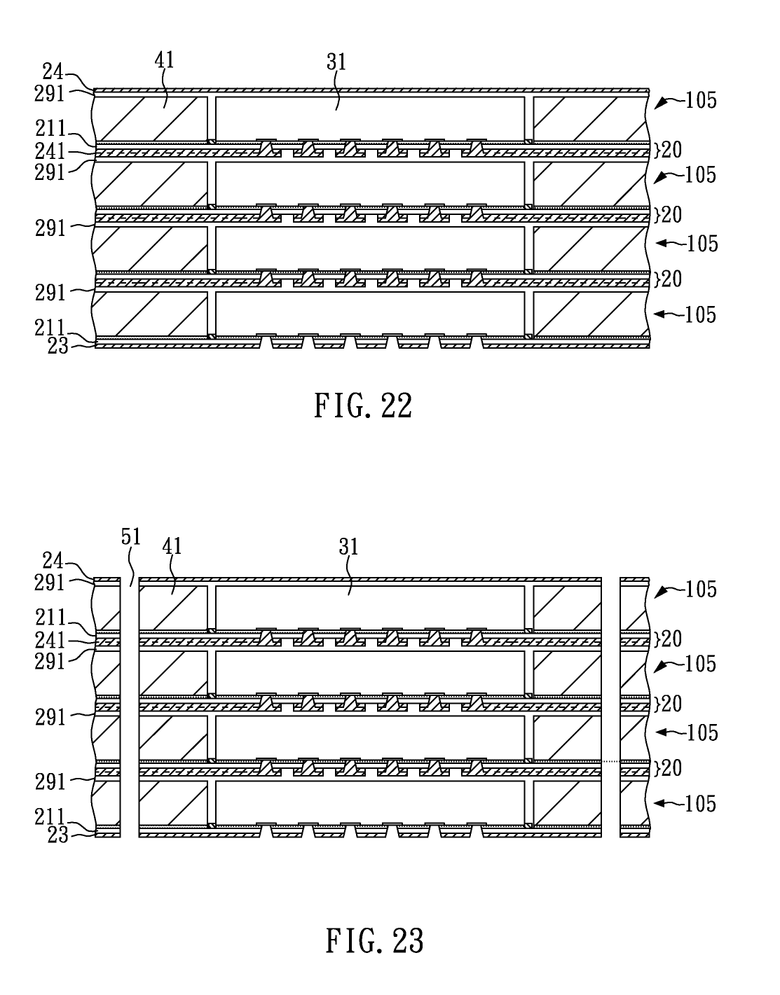

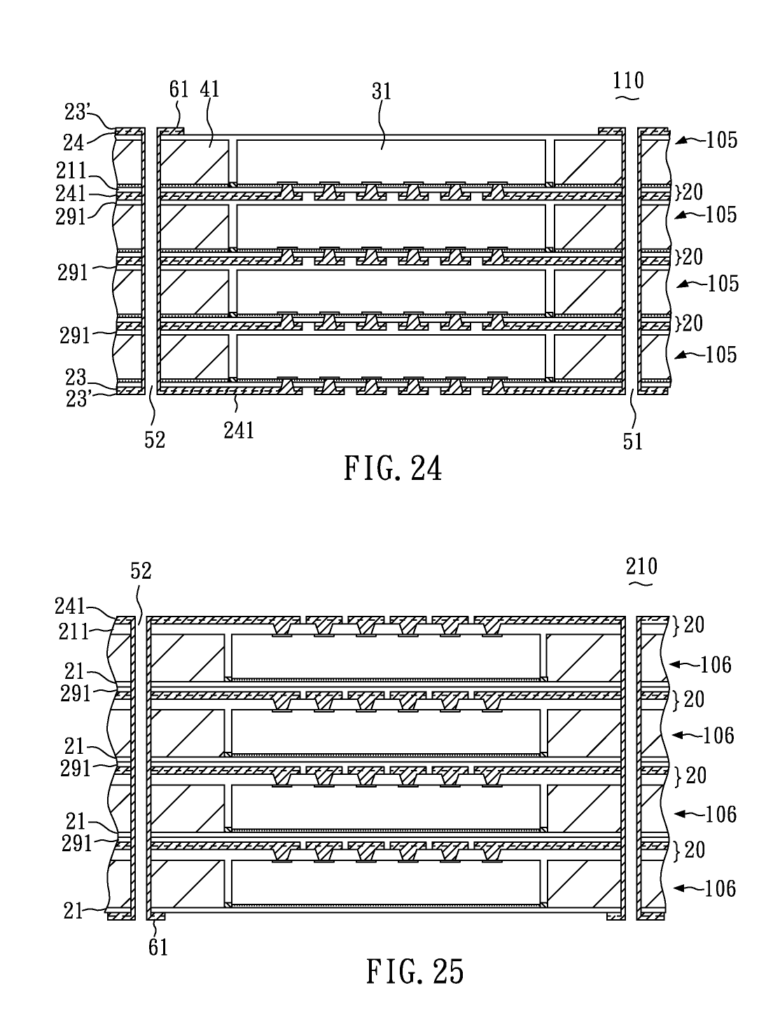

FIG. 2A′ is a top view corresponding to FIG. 2′;

FIGS. 2B-2E are top views of various stopper patterns that can be practiced in the present invention;

FIGS. 3 and 3A are cross-sectional and top views, respectively, of the structure with a semiconductor device mounted thereon in accordance with an embodiment of the present invention;

FIGS. 4 and 4A are cross-sectional and top views, respectively, of the structure with a stiffener mounted thereon in accordance with an embodiment of the present invention;

FIGS. 5-9 are cross-sectional views showing a method of making a semiconductor assembly that includes a semiconductor device, a stopper, a stiffener and a build-up circuitry electrically connected to the semiconductor device in accordance with an embodiment of the present invention;

FIGS. 10 and 10A are cross-sectional and top views, respectively, of another semiconductor assembly that includes a semiconductor device, a stopper, a placement guide, a stiffener and a build-up circuitry electrically connected to the semiconductor device and the stiffener in accordance with another embodiment of the present invention;

FIGS. 11-14 are cross-sectional views showing a method of making yet another semiconductor assembly that includes a semiconductor device, a stopper, a stiffener and a build-up circuitry electrically connected to the semiconductor device and the stiffener in accordance with yet another embodiment of the present invention;

FIGS. 15-21 are cross-sectional views showing a method of making still another semiconductor assembly that includes a semiconductor device, a stopper, an encapsulant and a build-up circuitry electrically connected to the semiconductor device in accordance with still another embodiment of the present invention;

FIGS. 22-24 are cross-sectional views showing a method of making a stacking module with multiple vertically stacked semiconductor assemblies in accordance with an embodiment of the present invention; and

FIG. 25 is a cross-sectional view of another stacking module with multiple vertically stacked semiconductor assemblies in accordance with another embodiment of the present invention.

### DETAILED DESCRIPTION OF THE INVENTION

Hereafter, examples will be provided to illustrate the embodiments of the present invention. Other advantages and effects of the invention will become more apparent from the disclosure of the present invention. It should be noted that these accompanying figures are simplified. The quantity, shape and size of components shown in the figures may be modified according to practically conditions, and the arrangement of components may be more complex. Other various aspects also may be practiced or applied in the invention, and various modifications and variations can be made without departing from the spirit of the invention based on various concepts and applications.

### Embodiment 1

FIGS. 1 and 2 are cross-sectional views showing a method of forming a stopper on a dielectric layer in accordance with an embodiment of the present invention, and FIG. 2A is a top view corresponding to FIG. 2.

FIG. 1 is a cross-sectional view of a laminate substrate that includes metal layer 11, dielectric layer 21 and support plate 23. Metal layer 11 is illustrated as a copper layer with a thickness of 35 microns. However, metal layer 11 can also be made of other various metal materials and is not limited to a copper layer. Besides, metal layer 11 can be deposited on dielectric layer 21 by numerous techniques including lamination, electroplating, electroless plating, evaporating, sputtering, and their combinations as a single layer or multiple layers, and preferably has a thickness in a range of 10 to 200 microns.

Dielectric layer 21 typically is made of epoxy resin, glass-epoxy, polyimide and the like and has a thickness of 50 microns. In this embodiment, dielectric layer 21 is sandwiched between metal layer 11 and support plate 23. However, support plate 23 may be omitted in some embodiments. Support plate 23 typically is made of copper, but copper alloys or other materials are also doable. The thickness of support plate 23 can range from 25 to 1000 microns, and preferably ranges from 35 to 100 microns in consideration of process and cost. In this embodiment, support plate 23 is illustrated as a copper plate with a thickness of 35 microns.

FIGS. 2 and 2A are cross-sectional and top views, respectively, of the structure with stopper 113 formed on dielectric layer 21. Stopper 113 can be formed by removing selected portions of metal layer 11 using photolithography and wet etching. In this illustration, stopper 113 consists of plural metal posts in a rectangular frame array and conforms to four sides of a semiconductor device subsequently disposed on dielectric layer 21. However, stopper patterns are not limited thereto and can be other various patterns against undesirable movement of the subsequently disposed semiconductor device.

FIGS. 1′ and 2′ are cross-sectional views showing an alternative method of forming a stopper on a dielectric layer, and FIG. 2A′ is a top view corresponding to FIG. 2′.

FIG. 1′ is a cross-sectional view of a laminate substrate with a set of cavities 111. The laminate substrate includes metal layer 11, dielectric layer 21 and support plate 23 as above mentioned, and cavities 111 are formed by removing selected portions of metal layer 11.

FIGS. 2′ and 2A′ are cross-sectional and top views, respectively, of the structure with stopper 113 formed on dielectric layer 21. Stopper 113 can be formed by dispensing or printing a photosensitive plastic material (e.g., epoxy, polyimide, etc.) or non-photosensitive material into cavities 111, followed by removing overall metal layer 11. Herein, stopper 113 is illustrated as an array of plural resin posts and conforms to two diagonal corners of a subsequently disposed semiconductor device.

FIGS. 2B-2E are top views of other various stopper patterns for reference. For instance, stopper 113 may consist of a continuous or discontinuous strip and conform to four sides (as shown FIGS. 2B and 2C), two diagonal corners or four corners (as shown in FIGS. 2D and 2E) of a subsequently disposed semiconductor device.

FIGS. 3-9 are cross-sectional views showing a method of making a semiconductor assembly that includes a semiconductor device, a stopper, a stiffener and build-up circuitry in accordance with an embodiment of the present invention.

As shown in FIG. 9, semiconductor assembly 101 includes semiconductor device 31, stopper 113, stiffener 41 and build-up circuitry 20. Semiconductor device 31 includes active surface 311, inactive surface 313 opposite to active surface 311, and contact pads 312 at active surface 311. Build-up circuitry 20 is electrically connected to semiconductor device 31 and includes first insulating layer 211, first conductive traces 241, second insulating layer 261 and second conductive traces 281 which include interconnect pads 284. Stopper 113 extends from first insulating layer 211 of build-up circuitry 20 in the upward direction and is in close proximity to peripheral edges of semiconductor device 31. Stopper 113 as well as semiconductor device 31 are aligned with and extend into aperture 411 of stiffener 41.

FIGS. 3 and 3A are cross-sectional and top views, respectively, of the structure with semiconductor device 31 such as a semiconductor chip mounted on dielectric layer 21 using adhesive 131. Semiconductor device 31 includes active surface 311, inactive surface 313 opposite to active surface 311, and contact pads 312 at active surface 311.

Stopper 113 can serve as a placement guide for semiconductor device 31, and thus semiconductor device 31 is precisely placed at a predetermined location with its active surface 311 facing dielectric layer 21. Stopper 113 extends from dielectric layer 21 beyond active surface 311 of semiconductor device 31 in the upward direction and is laterally aligned with and laterally extends beyond four sides of semiconductor device 31 in the lateral directions. As stopper 113 is in close proximity to and conforms to four lateral surfaces of semiconductor device 31 in lateral directions and adhesive 131 under semiconductor device 31 is lower than stopper 113, any undesirable movement of semiconductor device 31 due to adhesive curing can be avoided. Preferably, a gap in between semiconductor device 31 and stopper 113 is in a range of about 0.001 to 1 mm.

FIGS. 4 and 4A are cross-sectional and top views, respectively; of the structure with stiffener 41 mounted on dielectric layer 21 using adhesive 131. Semiconductor device 31 and stopper 113 are aligned with and inserted into aperture 411 of stiffener 41 and stiffener 41 is mounted on dielectric layer 21 using adhesive 131. Aperture 411 is formed by mechanical drilling through stiffener 41 and can be formed with other techniques such as punching and laser cutting. Stiffener 41 is illustrated as an epoxy sheet with a thickness of about the same to that of the semiconductor chip, but also can be other single layer or multi-layer structures, such as a multi-layer circuit board or a metal sheet.

Semiconductor device 31 and the inner wall of aperture 411 are spaced from one another by stopper 113. Stopper 113 is in close proximity to and laterally aligned with four inner walls of aperture 411 and adhesive 131 under stiffener 41 is lower than stopper 113, and thus any undesirable movement of stiffener 41 also can be avoided before adhesive 131 is fully cured. Optionally, a bonding material (not shown in the figure) can be added between semiconductor device 31 and stiffener 41 to enhance rigidity.

FIG. 5 is a cross-sectional view of the structure showing first via openings 213 formed through adhesive 131, dielectric layer 21 and support plate 23 to expose contact pads 312. First via openings 213 may be formed by numerous techniques including laser drilling, plasma etching and photolithography. Laser drilling can be enhanced by a pulsed laser. Alternatively, a scanning laser beam with a metal mask can be used. For instance, copper can be etched first to create a metal window followed by laser. First via openings 213 typically have a diameter of 50 microns, and dielectric layer 21 is considered first insulating layer 211 of build-up circuitry.

Referring now to FIG. 6, first conductive traces 241 are formed on first insulating layer 211 by depositing plated layer 23′ on support plate 23 and into first via openings 213 and then patterning support plate 23 and plated layer 23′ thereon. Alternatively, in some embodiments which apply a laminate substrate without support plate 23 or remove support plate 23 after the step illustrated in FIG. 4, the dielectric layer 21 can be directly metallized to form first conductive traces 241 after forming first via openings 213.

Plated layer 23′ can be deposited by numerous techniques including electroplating, electroless plating, evaporating, sputtering, and their combinations as a single layer or multiple layers. For instance, plated layer 23′ is deposited by first dipping the structure in an activator solution to render first insulating layer 211 catalytic to electroless copper, then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, support plate 23 and plated layer 23′ can be patterned to form first conductive traces 241 by numerous techniques including wet etching, electro-chemical etching, laser-assist etching, and their combinations with an etch mask (not shown) thereon that defines first conductive traces 241. Accordingly, first conductive traces 241 extend from first insulating layer 211 in the downward direction, extend laterally on first insulating layer 211 and extend into first via openings 213 in the upward direction to form first conductive vias 243 in electrical contact with contact pads 312.

Support plate 23 and plated layer 23′ thereon are shown as a single layer for convenience of illustration. The boundary (shown in phantom) between the metal layers may be difficult or impossible to detect since copper is plated on copper. However, the boundary between plated layer 23′ and first insulating layer 211 is clear.

FIG. 7 is a cross-sectional view of the structure showing second insulating layer 261 disposed on first conductive traces 241 and first insulating layer 211. Second insulating layer 261 can be epoxy resin, glass-epoxy, polyimide and the like deposited by numerous techniques including film lamination, spin coating, roll coating, and spray-on deposition and typically has a thickness of 50 microns. Preferably, first insulating layer 211 and second insulating layer 261 are the same material.

FIG. 8 is a cross-sectional view of the structure showing second via openings 263 formed through second insulating layer 261 to expose selected portions of first conductive traces 241. Like first via openings 213, second via openings 263 can be formed by numerous techniques including laser drilling, plasma etching and photolithography and typically have a diameter of 50 microns. Preferably, first via openings 213 and second via openings 263 have the same size.

Referring now to FIG. 9, second conductive traces 281 are formed on second insulating layer 261. Second conductive traces 281 extend from second insulating layer 261 in the downward direction, extend laterally on second insulating layer 261 and extend into second via openings 263 in the upward direction to form second conductive vias 283 in electrical contact with first conductive traces 241.

Second conductive traces 281 can be deposited as a conductive layer by numerous techniques including electrolytic plating, electroless plating, sputtering, and their combinations and then patterned by numerous techniques including wet etching, electro-chemical etching, laser-assist etching, and their combinations with an etch mask (not shown) thereon that defines second conductive traces 281. Preferably, first conductive traces 241 and second conductive traces 281 are the same material with the same thickness.

Accordingly, as shown in FIG. 9, semiconductor assembly 101 is accomplished and includes semiconductor device 31, stopper 113, stiffener 41 and build-up circuitry 20. In this illustration, build-up circuitry 20 includes first insulating layer 211, first conductive traces 241, second insulating layer 261 and second conductive traces 281.

Semiconductor device 31 and stiffener 41 are attached onto first insulating layer 211 through adhesive 131 that contacts and is sandwiched between active surface 311 of semiconductor device 31 and first insulating layer 211 and between stiffener 41 and first insulating layer 211, and are spaced from each other by stopper 113 between semiconductor device 31 and stiffener 41. Stopper 113 extends from first insulating layer 211 of build-up circuitry 20 in the upward direction and is in close proximity to peripheral edges of semiconductor device 31 and inner walls of aperture 411. Adhesive 131 contacts and is coplanar with stopper 113 in the downward direction and is lower than stopper 113 in the upward direction. First conductive traces 241 of build-up circuitry 20 directly contact semiconductor device 31 at contact pads 312, and thus the electrical connection between semiconductor device 31 and build-up circuitry 20 is devoid of solder.

### Embodiment 2

FIGS. 10 and 10A are cross-sectional and top views, respectively, of another semiconductor assembly 102 with placement guide 115 in close proximity to the outer peripheral edges of stiffener 41 and additional first conductive vias 243 in direct contact with stiffener 41 in accordance with another embodiment of the present invention.

In this embodiment, semiconductor assembly 102 is manufactured in a manner similar to that illustrated in Embodiment 1, except that placement guide 115 is simultaneously formed during stopper 113 formation by removing selected portions of metal layer 11 to accurately confine the placement location of stiffener 41 and additional first conductive vias 243 are formed in direct contact with stiffener 41. Placement guide 115 extends from first insulating layer 211 beyond the attached surface of stiffener 41 in the upward direction and is laterally aligned with and laterally extends beyond four outer lateral surfaces of stiffener 41 in the lateral directions. Placement guide 115 is illustrated as plural metal posts and conforms to four outer sides of stiffener 41 in lateral directions. However, placement guide 115 is not limited to the illustrated pattern and can be designed in other various patterns. As placement guide 115 is in close proximity to and conforms to four outer lateral surfaces of stiffener 41 in lateral directions and adhesive 131 under stiffener 41 is lower than placement guide 115, any undesirable movement of stiffener 41 due to adhesive curing can be avoided. Preferably, a gap in between the outer peripheral edges of stiffener 41 and placement guide 115 is in a range of about 0.001 to 1 mm.

### Embodiment 3

FIGS. 11-14 are cross-section views showing a method of making yet another semiconductor assembly that includes a support plate, a dielectric layer, a semiconductor device, a stopper, a stiffener and build-up circuitry in accordance with yet another embodiment of the present invention.

For purposes of brevity, any description in Embodiment 1 is incorporated herein insofar as the same is applicable, and the same description need not be repeated.

FIG. 11 is a cross-sectional view of the structure which is manufactured by the same steps shown in FIGS. 1-4, except that semiconductor device 31 is mounted on dielectric layer 21 with its inactive surface 313 facing dielectric layer 21 and support plate 23 is illustrated as a copper plate with a thickness of 50 microns.

FIG. 12 is a cross-sectional view of the structure with first insulating layer 211 formed on active surface 311 of semiconductor device 31 and stiffener 41 in the upward direction. First insulating layer 211 covers semiconductor device 31, stiffener 41 and stopper 113 in the upward direction, and extends into the gap between semiconductor device 31 and stiffener 41 in aperture 411.

FIG. 13 is a cross-sectional view of the structure showing first via openings 213 formed through first insulating layer 211. First via openings 213 are aligned with and expose contact pads 312 of semiconductor device 31 and selected portions of stiffener 41.

Referring now to FIG. 14, first conductive traces 241 are formed on first insulating layer 211. First conductive traces 241 extend from first insulating layer 211 in the upward direction, extend laterally on first insulating layer 211 and extend into first via openings 213 in the downward direction to form first conductive vias 243 in electrical contact with contact pads 312 and stiffener 41.

Accordingly, as shown in FIG. 14, semiconductor assembly 103 is accomplished and includes support plate 23, dielectric layer 21, semiconductor device 31, stopper 113, stiffener 41, and build-up circuitry 20. In this illustration, build-up circuitry 20 contacts and covers semiconductor device 31 and stiffener 41 in the upward direction and includes first insulating layer 211 and first conductive traces 241. Semiconductor device 31 and stiffener 41 are mounted on dielectric layer 21 using adhesive 131 that contacts and is sandwiched between inactive surface 313 of semiconductor device 31 and dielectric layer 21 and between stiffener 41 and dielectric layer 21, and are spaced from each other by stopper 113 between semiconductor device 31 and stiffener 41. Stopper 113 extends from dielectric layer 211 beyond inactive surface 313 of semiconductor device 31 in the upward direction and is located in close proximity to and laterally aligned with peripheral edges of semiconductor device 31 to accurately confine the placement location of semiconductor device 31.

### Embodiment 4

FIGS. 15-21 are cross-section views showing a method of making still another semiconductor assembly that includes a semiconductor device, a stopper, an encapsulant and build-up circuitry in accordance with still another embodiment of the present invention.

For purposes of brevity, any description in Embodiment 1 is incorporated herein insofar as the same is applicable, and the same description need not be repeated.

FIG. 15 is a cross-sectional view of the structure which is manufactured by the steps shown in FIGS. 1-3.

FIG. 16 is a cross-sectional view of the structure with encapsulant 71 such as molding compound that contacts and covers semiconductor device 31, stopper 113, and dielectric layer 21 in the upward direction. Encapsulant 71 extends from semiconductor device 31, stopper 113 and dielectric layer 21 in the upward direction and laterally covers and surrounds and conformally coats the peripheral side surfaces of semiconductor device 31 and stopper 113 and extends laterally from semiconductor device 31 and stopper 113 to peripheral edges of the structure to provide protection for semiconductor device 31.

FIG. 17 is a cross-sectional view of the structure showing first via openings 213 formed through support plate 23, dielectric layer 21 and adhesive 131. First via openings 213 are aligned with and expose contact pads 312, and dielectric layer 21 is considered first insulating layer 211 of build-up circuitry.

Referring now to FIG. 18, first conductive traces 241 are formed on first insulating layer 211 by depositing plated layer 23′ on support plate 23 and into first via openings 213 and then patterning support plate 23 and plated layer 23′ thereon. Plated layer 23′ covers and extends from support plate 23 in the downward direction and extends into first via openings 213 in the upward direction to form first conductive vias 243 in electrical contact with contact pads 312.

Support plate 23 and plated layer 23′ thereon are shown as a single layer for convenience of illustration. The boundary (shown in phantom) between the metal layers may be difficult or impossible to detect since copper is plated on copper. However, the boundary between plated layer 23′ and first insulating layer 211 is clear.

FIG. 19 is a cross-sectional view of the structure showing second insulating layer 261 disposed on first conductive traces 241 and first insulating layer 211. Second insulating layer 261 covers and extends from first insulating layer 211 and first conductive traces 241 in the downward direction.

FIG. 20 is a cross-sectional view of the structure showing second via openings 263 formed through second insulating layer 261. Second via openings 263 are aligned with and expose selected portions of first conductive traces 241.

Referring now to FIG. 21, second conductive traces 281 are formed on second insulating layer 261. Second conductive traces 281 extend from second insulating layer 261 in the downward direction, extend laterally on second insulating layer 261 and extend into second via openings 263 in the upward direction to form second conductive vias 283 in electrical contact with first conductive traces 241.

Accordingly, as shown in FIG. 21, semiconductor assembly 104 is accomplished and includes semiconductor device 31, stopper 113, encapsulant 71, and build-up circuitry 20. In this illustration, build-up circuitry 20 covers semiconductor device 31, stopper 113 and encapsulant 71 in the downward direction and includes first insulating layer 211, first conductive traces 241, second insulating layer 261 and second conductive traces 281. Semiconductor device 31 is affixed on build-up circuitry 20 using adhesive 131 that contacts and is sandwiched between active surface 311 of semiconductor device 31 and first insulating layer 211. Stopper 113 extends from first insulating layer 211 beyond active surface 311 of semiconductor device 31 in the upward direction and is located in close proximity to and laterally aligned with peripheral edges of semiconductor device 31 to accurately confine the placement location of semiconductor device 31.

### Embodiment 5

FIGS. 22-24 are cross-section views showing a method of making a stacking module that includes multiple vertically stacked semiconductor assemblies in accordance with one preferred embodiment of the present invention.

FIG. 22 is a cross-sectional view of the structure with interlayer dielectrics 291 sandwiched between two neighboring semiconductor assemblies 105 and between top metal layer 24 and top semiconductor assembly 105. Each semiconductor assembly 105 is manufactured by the steps illustrated in FIGS. 1-6, except that the bottom assembly 105 is not provided with conductive traces yet. Semiconductor assembly 105 are vertically stacked and bonded to one another using interlayer dielectric 291 that contacts and is sandwiched between build-up circuitry 20 of upper semiconductor assembly 105 and semiconductor device 31 of lower semiconductor assembly 105 and between build-up circuitry 20 of upper semiconductor assembly 105 and stiffener 41 of lower semiconductor assembly 105. Meanwhile, additional metal layer 24 is also bonded to semiconductor device 31 and stiffener 41 of top semiconductor assembly 105 using interlayer dielectric 291. In this illustration, interlayer dielectric 291 further extends into the gap between semiconductor device 31 and stiffener 41 of lower semiconductor assembly 105.

FIG. 23 is a cross-sectional view of the structure with through-holes 51. Through-holes 51 extend through top metal layer 24, semiconductor assemblies 105 and interlayer dielectrics 291 in the vertical direction. Through-holes 51 are formed by mechanical drilling and can be formed by other techniques such as laser drilling and plasma etching with or without wet etching.

Referring now to FIG. 24, bottom assembly 105 is provided with first conductive traces 241 by depositing plated layer 23′ on support plate 23 and then patterning the combination of support plate 23 and plated layer 23′, and terminals 61 are formed on top interlayer dielectric 291 by depositing plated layer 23′ on metal layer 24 and patterning the combination of metal layer 24 and plated layer 23′. Also, plated layer 23′ is further deposited in through-holes 51 to provide plated through-holes 52. Accordingly, stacking module 110 is accomplished and includes multiple semiconductor assemblies 105, interlayer dielectric 291, terminals 61 and plated through-holes 52. Each semiconductor assembly 105 includes semiconductor device 31, stopper 113, stiffener 41 and build-up circuitry 20. In this illustration, build-up circuitry 20 includes first insulating layer 211 and first conductive traces 241. Plated through-holes 52 extend through interlayer dielectrics 291 and semiconductor assemblies 105 to provide electrical connection between semiconductor assemblies 105 and terminals 61.

### Embodiment 6

FIG. 25 is a cross-section view of another stacking module 210 with multiple vertically stacked semiconductor assemblies 106 in accordance with another embodiment of the present invention. Semiconductor assemblies 106 are manufactured by the steps illustrated in FIGS. 11-14 plus a step of removing support plate 23 and vertically stacked and bonded to one another using interlayer dielectrics 291.

Interlayer dielectrics 291 contact and are sandwiched between dielectric layer 21 of upper semiconductor assembly 106 and build-up circuitry 20 of lower semiconductor assembly 106. In this illustration, build-up circuitry 20 includes first insulating layer 211 and first conductive traces 241. Plated through-holes 52 extend through interlayer dielectrics 291 and semiconductor assemblies 106 to provide electrical connection between semiconductor assemblies 106 and terminals 61 that extend from dielectric layer 21 of bottom semiconductor assembly 106 in the downward direction.

The semiconductor assemblies and stacking modules described above are merely exemplary. Numerous other embodiments are contemplated. In addition, the embodiments described above can be mixed-and-matched with one another and with other embodiments depending on design and reliability considerations. For instance, the semiconductor assembly may include multiple sets of stoppers to accurately define the relative positions of multiple additional semiconductor devices, passive components or other electronic devices, and the build-up circuitry can include additional conductive traces to accommodate additional semiconductor devices, passive components or other electronic devices. Likewise, the stiffener can include multiple apertures to accommodate additional semiconductor devices, passive components or other electronic devices.

The semiconductor device can be a packaged or unpackaged chip. Furthermore, the semiconductor device can be a bare chip, LGA, or QFN, etc. The stopper can be customized for the semiconductor device. For instance, the stopper can have a pattern that defines a square or rectangular area with the same or similar topography as the semiconductor device. External heat dissipation element such as heat spreader or heat sink can be attached to the semiconductor device by thermally conductive adhesive or soldering material. The external heat dissipation element can also be attached to the stiffener to extend the contact area and enhance the efficiency of the dissipation pathway for the semiconductor device.

The term “adjacent” refers to elements that are integral (single-piece) or in contact (not spaced or separated from) with one another. For instance, the first conductive trace is adjacent to the active surface but not the inactive surface.

The term “overlap” refers to above and extending within a periphery of an underlying element. Overlap includes extending inside and outside the periphery or residing within the periphery. For instance, in the position that the stopper extends from the dielectric layer in the upward direction, the stiffener overlaps the dielectric layer since an imaginary vertical line intersects the stiffener and the dielectric layer, regardless of whether another element such as the adhesive is between the stiffener and the dielectric layer and is intersected by the line, and regardless of whether another imaginary vertical line intersects the dielectric layer but not the stiffener (within the aperture of the stiffener). Likewise, the adhesive overlaps the dielectric layer, the stiffener overlaps the adhesive and the adhesive is overlapped by the stiffener. Moreover, overlap is synonymous with over and overlapped by is synonymous with under or beneath.

The term “contact” refers to direct contact. For instance, the conductive trace contacts the active surface but not the inactive surface.

The term “cover” refers to incomplete and complete coverage in a vertical and/or lateral direction. For instance, in the position that the inactive surface of the semiconductor device faces the upward direction, the build-up circuitry covers the semiconductor device in the downward direction regardless of whether another element such as the adhesive is between the semiconductor device and the build-up circuitry, and the encapsulant cover the semiconductor device in the upward direction.

The term “layer” refers to patterned and un-patterned layers. For instance, the metal layer of the laminate substrate can be an un-patterned blanket sheet before photolithography and wet etching. Furthermore, a layer can include stacked layers.

The terms “opening” and “aperture” refer to a through hole and are synonymous. For instance, in the position that the stopper extends from the dielectric layer in the upward direction, the semiconductor device is exposed by the stiffener in the upward direction when it is inserted into the aperture in the stiffener.

The term “inserted” refers to relative motion between elements. For instance, the semiconductor device is inserted into the aperture regardless of whether the stiffener is stationary and the semiconductor device moves towards the stiffener, the semiconductor device is stationary and the stiffener moves towards the semiconductor device or the semiconductor device and the stiffener both approach the other. Furthermore, the semiconductor device is inserted (or extends) into the aperture regardless of whether it goes through (enters and exits) or does not go through (enters without exiting) the aperture.

The phrase “aligned with” refers to relative position between elements regardless of whether elements are spaced from or adjacent to one another or one element is inserted into and extends into the other element. For instance, the stopper is laterally aligned with the semiconductor device since an imaginary horizontal line intersects the stopper and the semiconductor device, regardless of whether another element is between the stopper and the semiconductor device and is intersected by the line, and regardless of whether another imaginary horizontal line intersects the semiconductor device but not the stopper or intersects the stopper but not the semiconductor device. Likewise, the first via opening is aligned with the contact pads of the semiconductor device, and the semiconductor device and the stopper are aligned with the aperture.

The phrase “in close proximity to” refers to a gap between elements not being wider than the maximum acceptable limit. As known in the art, when the gap between the semiconductor device and the stopper is not narrow enough, the location error of the semiconductor device due to the lateral displacement of the semiconductor device within the gap may exceed the maximum acceptable error limit. Once the location error of the semiconductor device goes beyond the maximum limit, it is impossible to align the contact pad with a laser beam, resulting in the electrical connection failure between the semiconductor device and the build-up circuitry. According to the pad size of the semiconductor device, those skilled in the art can ascertain the maximum acceptable limit for a gap between the semiconductor device and the stopper through trial and error to prevent the electrical connection failure between the semiconductor device and the build-up circuitry. Thereby, the description “the stopper is in close proximity to the peripheral edges of the semiconductor device” means that the gap between the peripheral edges of the semiconductor device and the stopper is narrow enough to prevent the location error of the semiconductor device from exceeding the maximum acceptable error limit.

The phrase “mounted on” includes contact and non-contact with a single or multiple support element(s). For instance, the semiconductor device is mounted on the dielectric layer regardless of whether it contacts the dielectric layer or is separated from the dielectric layer by an adhesive.

The phrase “electrical connection” or “electrically connects” or “electrically connected” refers to direct and indirect electrical connection. For instance, the first conductive trace provides an electrical connection between the interconnect pad and the contact pad of the semiconductor device regardless of whether the first conductive trace is adjacent to the interconnect pad or electrically connected to the interconnect pad by the second conductive trace.

The term “above” refers to upward extension and includes adjacent and non-adjacent elements as well as overlapping and non-overlapping elements. For instance, in the position that the encapsulant faces the upward direction, the stopper extends above, is adjacent to and protrudes from the dielectric layer.

The term “below” refers to downward extension and includes adjacent and non-adjacent elements as well as overlapping and non-overlapping elements. For instance, in the position that the encapsulant faces the upward direction, the build-up circuitry extends below, is adjacent to and protrudes from the adhesive and the encapsulant in the downward direction. Likewise, the build-up circuitry extends below the semiconductor device even though it is not adjacent to the semiconductor device.

The “first vertical direction” and “second vertical direction” do not depend on the orientation of the assembly, as will be readily apparent to those skilled in the art. For instance, the active surface of the semiconductor device faces the first vertical direction and the inactive surface of the semiconductor device faces the second vertical direction regardless of whether the assembly is inverted. Likewise, the stopper is “laterally” aligned with the semiconductor device in a lateral plane regardless of whether the assembly is inverted, rotated or slanted. Thus, the first and second vertical directions are opposite one another and orthogonal to the lateral directions, and a lateral plane orthogonal to the first and second vertical directions intersects laterally aligned elements. Furthermore, the first vertical direction is the downward direction and the second vertical direction is the upward direction in the position that the active surface of the semiconductor device faces the downward direction, and the first vertical direction is the upward direction and the second vertical direction is the downward direction in the position that the active surface of the semiconductor device faces the upward direction.

The semiconductor assembly and the stacking module using the same according to the present invention have numerous advantages. The semiconductor assembly and the stacking module are reliable, inexpensive and well-suited for high volume manufacture. The stiffener provides the mechanical support, dimensional stability and controls the overall flatness and the thermal expansion of the build-up circuitry such that the semiconductor device can be securely connected to the build-up circuitry under thermal cycling even though the coefficient of thermal expansion (CTE) between them may be different. The direct electrical connection without solder between the semiconductor device and the build-up circuitry is advantageous to high I/O and high performance. Particularly, the stopper can accurately confine the placement location of the semiconductor device and avoid the electrical connection failure between the semiconductor device and the build-up circuitry resulted from the lateral displacement of the semiconductor device, thereby improving the manufacturing yield greatly.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional packaging techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

Various changes and modifications to the embodiments described herein will be apparent to those skilled in the art. For instance, the materials, dimensions, shapes, sizes, steps and arrangement of steps described above are merely exemplary. Such changes, modifications and equivalents may be made without departing from the spirit and scope of the present invention as defined in the appended claims.

Although the present invention has been explained in relation to its preferred embodiment, it is to be understood that many other possible modifications and variations can be made without departing from the spirit and scope of the invention as hereinafter claimed.

What is claimed is:

1. A method of making a semiconductor assembly with a built-in stopper, comprising:
forming a stopper on a dielectric layer;
mounting a semiconductor device on the dielectric layer using the stopper as a placement guide for the semiconductor device that includes an active surface with a contact pad thereon and an inactive surface, wherein the active surface faces a first vertical direction, the inactive surface faces a second vertical direction opposite the first vertical direction, and the stopper is located in close proximity to and laterally aligned with and laterally extends beyond peripheral edges of the semiconductor device in lateral directions orthogonal to the vertical directions;
attaching a stiffener to the dielectric layer, including aligning the semiconductor device and the stopper within an aperture of the stiffener; and
forming a build-up circuitry that covers the stopper, the semiconductor device and the stiffener in the first vertical direction and includes a first conductive via that directly contacts the contact pad of the semiconductor device to provide an electrical connection between the semiconductor device and the build-up circuitry.

2. The method of claim 1, wherein the electrical connection between the semiconductor device and the build-up circuitry is devoid of solder.

3. The method of claim 1, wherein forming the stopper on the dielectric layer includes:
providing a laminate substrate that includes a metal layer and the dielectric layer; and then
removing a selected portion of the metal layer to form the stopper.

4. The method of claim 1, forming the stopper on the dielectric layer includes:
providing a laminate substrate that includes a metal layer and the dielectric layer; then
removing a selected portion of the metal layer to form a recessed portion; then
depositing a plastic material into the recessed portion; and then removing a remaining portion of the metal layer.

5. The method of claim 1, wherein the semiconductor device is mounted on the dielectric layer with the active surface facing the dielectric layer and the stopper extends from the dielectric layer in the second vertical direction.

6. The method of claim 5, wherein the semiconductor device is attached to the dielectric layer using an adhesive that contacts and is sandwiched between the semiconductor device and the dielectric layer.

7. The method of claim 6, wherein the adhesive contacts and is coplanar with the stopper in the first vertical direction and is lower than the stopper in the second vertical direction.

8. The method of claim 5, wherein forming the build-up circuitry includes:
providing a first insulating layer that includes the dielectric layer and covers the stopper, the semiconductor device and the stiffener in the first vertical direction; then
forming a first via opening that extends through the first insulating layer and is aligned with the contact pad of the semiconductor device; and then
forming a first conductive trace that extends from the first insulating layer in the first vertical direction and extends laterally on the first insulating layer and extends through the first via opening in the second vertical direction to form the first conductive via in direct contact with the contact pad of the semiconductor device.

9. The method of claim 8, wherein forming the build-up circuitry includes:
forming an additional first via opening that extends through the first insulating layer and is aligned with the stiffener; and then
forming the first conductive trace that extends through the additional first via opening in the second vertical direction to form an additional first conductive via in direct contact with the stiffener.

10. The method of claim 1, wherein the semiconductor device is mounted on the dielectric layer with the inactive surface facing the dielectric layer and the stopper extends from the dielectric layer in the first vertical direction.

11. The method of claim 10, the semiconductor device is attached to the dielectric layer using an adhesive that contacts and is sandwiched between the semiconductor device and the dielectric layer.

12. The method of claim 11, wherein the adhesive contacts and is coplanar with the stopper in the second vertical direction and is lower than the stopper in the first vertical direction.

13. The method of claim 10, wherein forming the build-up circuitry includes:
providing a first insulating layer that covers the stopper, the semiconductor device and the stiffener in the first vertical direction; then
forming a first via opening that extends through the first insulating layer and is aligned with the contact pad of the semiconductor device; and then
forming a first conductive trace that extends from the first insulating layer in the first vertical direction and extends laterally on the first insulating layer and extends through the first via opening in the second vertical direction to form the first conductive via in direct contact with the contact pad of the semiconductor device.

14. The method of claim 13, wherein forming the build-up circuitry includes:
forming an additional first via opening in the first insulating layer that is aligned with the stiffener; and then
forming the first conductive trace that extends through the additional first via opening in the second vertical direction to form an additional first conductive via in direct contact with the stiffener.

15. The method of claim 1, wherein the stopper include a continuous or discontinuous strip or an array of posts.

16. The method of claim 1, wherein a gap in between the semiconductor device and the stopper is in a range of 0.001 to 1 mm.

17. The method of claim 1, wherein the stopper has a height in a range of 10 to 200 microns.

18. The method of claim 1, wherein the stiffener is a laminated epoxy or polyimide.

19. A semiconductor assembly with a built-in stopper, comprising:
a semiconductor device that includes an active surface with a contact pad thereon and an inactive surface, wherein the active surface faces a first vertical direction and the inactive surface faces a second vertical direction opposite the first vertical direction;
the stopper that serves as a placement guide for the semiconductor device and is in close proximity to and laterally aligned with and laterally extends beyond peripheral edges of the semiconductor device in lateral directions orthogonal to the vertical directions;
a stiffener that includes an aperture with the semiconductor device and the stopper extending thereinto; and
a build-up circuitry that covers the stopper, the semiconductor device and the stiffener in the first vertical direction and includes a first insulating layer, a first via opening and a first conductive trace, wherein the first via opening in the first insulating layer is aligned with the contact pad of the semiconductor device, and the first conductive trace extends from the first insulating layer in the first vertical direction and extends through the first via opening in the second vertical direction and directly contacts the contact pad.

20. A method of making a semiconductor assembly with a built-in stopper, comprising:
forming a stopper on a dielectric layer;
mounting a semiconductor device on the dielectric layer using the stopper as a placement guide for the semiconductor device that includes an active surface with a contact pad thereon and an inactive surface, wherein the active surface faces a first vertical direction and is attached to the dielectric layer, the inactive surface faces a second vertical direction opposite the first vertical direction, and the stopper is located in close proximity to and laterally aligned with and laterally extends beyond peripheral edges of the semiconductor device in lateral directions orthogonal to the vertical directions;
depositing an encapsulant that covers the semiconductor device, the stopper and the dielectric layer from the second vertical direction and extends laterally from the semiconductor device and the stopper to peripheral edges of the assembly; and
forming a build-up circuitry that covers the stopper, the semiconductor device and the stiffener in the first vertical direction and includes a first conductive via that extends through the dielectric layer and directly contacts the contact pad of the semiconductor device to provide an electrical connection between the semiconductor device and the build-up circuitry.
